(19) United States
(12) Patent Application Publication
(10) Pub. No.: US 2020/0343167 A1
(43) Pub. Date: Oct. 29, 2020

(54) Leaded Semiconductor Package

(71) Applicant: Infineon Technologies AG, Neubiberg (DE)

(72) Inventors: Nurfarena Othman, Melaka (MY); Do Hyung Kim, Zorneding (DE); Swee Kah Lee, Melaka (MY); Mohd Rasydan Hakam Mohamad Tahir, Melaka (MY); Muhammad Muhammat Sanusi, Sungai Petani (MY); Ciprian Mircea Pavaluta, Bucharest (RO)

(21) Appl. No.: 16/393,898

(22) Filed: Apr. 24, 2019

(51) Int. Cl. H01L 23/495; H01L 23/31; H01L 21/56; H01L 21/48

(52) U.S. Cl. CPC H01L 23/49575; H01L 23/49555; H01L 21/4821; H01L 21/563; H01L 21/565; H01L 23/3114

(57) ABSTRACT

A semiconductor package includes a mold compound, a plurality of electrically conductive leads at least some of which transition from a first level within the mold compound to a second (different) level outside the mold compound, and a semiconductor die embedded in the mold compound and attached to the plurality of electrically conductive leads in a flip-chip configuration. One or more leads of the plurality of electrically conductive leads includes a first section terminating at a side face of the mold compound or protruding from the side face with a first end positioned outside a footprint of the mold compound and which terminates at the second level, and a second section embedded in the mold compound and having a second end which is positioned under the semiconductor die and exposed at a bottom side of the semiconductor package. Corresponding methods of manufacture are also described.

### BACKGROUND

Leaded semiconductor packages such as DSO (dual small out-line), QFP (quad flat package), SOP (small-outline package) like SSOP (shrink small-outline package) and TSOP (thin SOP), etc. include a semiconductor die attached to a die pad, and the semiconductor die and die pad are encapsulated in a mold compound. The molded construction results in high power limitations. The main thermal conductivity path of leaded semiconductor packages includes the drain leads and the board to which the package is attached. The source connection has even higher thermal impedance to the application board. As a result, conventional leaded semiconductor packages have a poor thermal conduction path to the top side of the package, since the top side is covered by mold compound, and to the bottom side of the package, since the bottom side is covered with solder.

Thus, there is a need for an improved molded semiconductor package with a more efficient thermal conduction path.

### SUMMARY

According to an embodiment of a semiconductor package, the semiconductor package comprises: a mold compound; a plurality of electrically conductive leads at least some of which transition from a first level within the mold compound to a second level outside the mold compound, the second level being different than the first level; and a semiconductor die embedded in the mold compound and attached to the plurality of electrically conductive leads in a flip-chip configuration. One or more leads of the plurality of electrically conductive leads comprises: a first section terminating at a side face of the mold compound, or protruding from the side face with a first end positioned outside a footprint of the mold compound and which terminates at the second level; and a second section embedded in the mold compound and having a second end which is positioned under the semiconductor die and exposed at a bottom side of the semiconductor package.

The semiconductor die may be attached to a horizontal third section of the one or more leads having the first section and the second section, the third section being interposed between the first section and the second section.

Separately or in combination, at least two leads of the plurality of electrically conductive leads each may comprise the first section and the second section so that at least two second lead ends are positioned under the semiconductor die and exposed at the bottom side of the semiconductor package, and the at least two second lead ends positioned under the semiconductor die and exposed at the bottom side of the semiconductor package may be electrically coupled to the same electric potential or to ground. The mold compound may be a laser-activatable mold compound having a laser-activated region at the bottom side of the semiconductor package and the laser-activated region may be plated with an electrically conductive material which connects the at least two second lead ends positioned under the semiconductor die and exposed at the bottom side of the semiconductor package. The laser-activated region may be formed in a recessed part of the mold compound at the bottom side of the semiconductor package and the recessed part may be surrounded by a thicker border of the mold compound.

Separately or in combination, the second end of the one or more leads of the plurality of electrically conductive leads may be exposed in a recessed part of the bottom side of the semiconductor package and wherein the recessed part may be surrounded by a thicker border of the mold compound.

Separately or in combination, at least two leads of the plurality of electrically conductive leads may each comprise the first section and the second section so that at least two second lead ends are positioned under the semiconductor die and exposed at the bottom side of the semiconductor package, and the first section of a first one of the at least two leads and the first section of a second one of the at least two leads may protrude from opposite side faces of the mold compound.

Separately or in combination, the plurality of electrically conductive leads may protrude from the mold compound below a horizontal centerline of the mold compound.

Separately or in combination, a side of the semiconductor die facing away from the plurality of electrically conductive leads may be exposed at a top side of the semiconductor package.

Separately or in combination, the semiconductor package may further comprise a metal block contacting the side of the semiconductor die to which the plurality of electrically conductive leads is attached, the metal block being exposed at the bottom side of the semiconductor package.

According to an embodiment of a method of manufacturing a semiconductor package, the method comprises: forming a plurality of electrically conductive leads from a leadframe, one or more leads of the plurality of electrically conductive leads comprising a first section and a second section; attaching a semiconductor die to the plurality of electrically conductive leads in a flip-chip configuration; and embedding the semiconductor die and the plurality of electrically conductive leads in a mold compound so that: at least some of the electrically conductive leads transition from a first level within the mold compound to a second level outside the mold compound, the second level being different than the first level; the first section of the one or more leads terminates at a side face of the mold compound, or protrudes from the side face with a first end positioned outside a footprint of the mold compound and which terminates at the second level; and the second section of the one or more leads is embedded in the mold compound and has a second end positioned under the semiconductor die and exposed at a bottom side of the semiconductor package.

The mold compound may be a laser-activatable mold compound, at least two leads of the plurality of leads may have the first section and the second section so that at least two second lead ends are positioned under the semiconductor die and exposed at the bottom side of the semiconductor package; and the method may further comprise: laser activating a region of the mold compound at the bottom side of the mold compound to form a laser-activated region; and plating the laser-activated region with an electrically conductive material which connects the at least two second lead ends positioned under the semiconductor die and exposed at the bottom side of the semiconductor package.

The method may further comprise forming a recess in the mold compound at the bottom side of the semiconductor package, the recess being surrounded by a thicker border of the mold compound, wherein the laser activating is performed on the recess in the mold compound to form the laser-activated region.

According to an embodiment of an electronic assembly, the electronic assembly comprises a board and a semiconductor package attached to the board. The semiconductor package comprises: a mold compound; a plurality of electrically conductive leads at least some of which transition from a first level within the mold compound to a second level outside the mold compound and connected to the board, the second level being different than the first level; and a semiconductor die embedded in the mold compound and attached to the plurality of electrically conductive leads in a flip-chip configuration, wherein one or more leads of the plurality of electrically conductive leads comprises: a first section terminating at a side face of the mold compound, or protruding from the side face with a first end positioned outside a footprint of the mold compound and which terminates at the second level and is connected to the board; and a second section embedded in the mold compound and having a second end which is positioned under the semiconductor die, exposed at a bottom side of the semiconductor package and connected to the board.

Those skilled in the art will recognize additional features and advantages upon reading the following detailed description, and upon viewing the accompanying drawings.

### BRIEF DESCRIPTION OF THE FIGURES

The elements of the drawings are not necessarily to scale relative to each other. Like reference numerals designate corresponding similar parts. The features of the various illustrated embodiments can be combined unless they exclude each other. Embodiments are depicted in the drawings and are detailed in the description which follows.

FIGS. 1A through 1C illustrate different views of an embodiment of a molded semiconductor package of the leaded type.

FIGS. 2A through 2E illustrate different views of the molded semiconductor package shown in FIGS. 1A through 10, prior to the molding process.

FIG. 3 illustrates a cross-sectional view of an embodiment of an electronic assembly that includes a board and the molded semiconductor package shown in FIGS. 1A through 2E attached to the board.

FIG. 4 illustrates a cross-sectional view of another embodiment of a molded semiconductor package of the leaded type.

FIGS. 5A through 5D illustrate different views of another embodiment of a molded semiconductor package of the leaded type.

FIGS. 6A through 6E illustrate different views of another embodiment of a molded semiconductor package of the leaded type,

FIG. 7 illustrates a flow diagram of an embodiment of manufacturing the semiconductor packages shown in FIGS. 1A through 6E, without a laser-activated region of the mold compound.

FIG. 8 illustrate a flow diagram of an embodiment of manufacturing the semiconductor packages shown in FIGS. 1A through 6E, with a laser-activated region of the mold compound.

### DETAILED DESCRIPTION

The embodiments described herein provide a molded semiconductor package of the leaded type and having a highly efficient thermal conduction path. The thermal conduction path is realized by one or more leads of the package which are attached to a semiconductor die included in the package and which extend under the semiconductor die and are exposed at the underside of the leaded package. The semiconductor die is attached to the leads in a flip-chip configuration. A molded semiconductor package with such a highly efficient thermal conduction path allows for a larger die in a small flip-chip package construction, increasing the ratio of die-to-package. The molded semiconductor package embodiments described herein allow for high current density with low EMI (electromagnetic interference). Bottom side cooling is provided via the exposed leads at the underside of the leaded package.

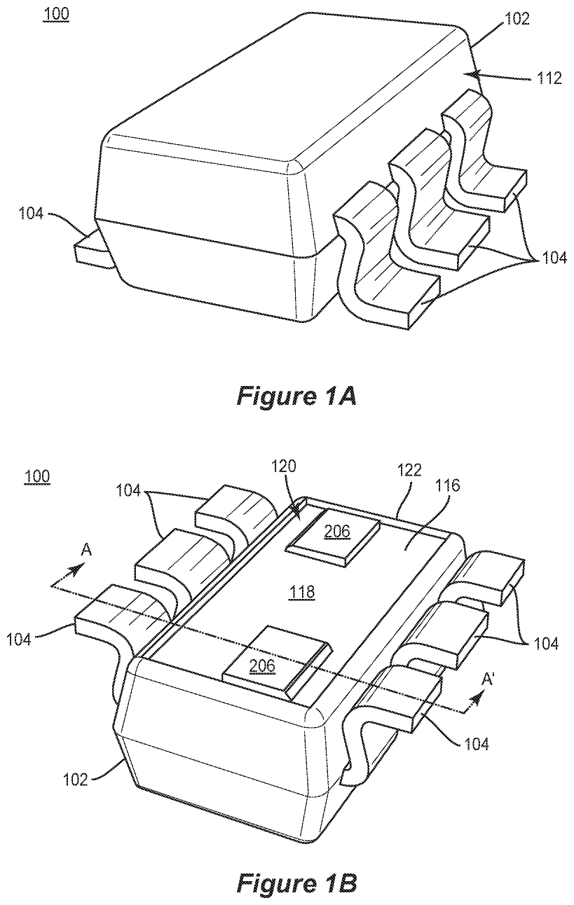

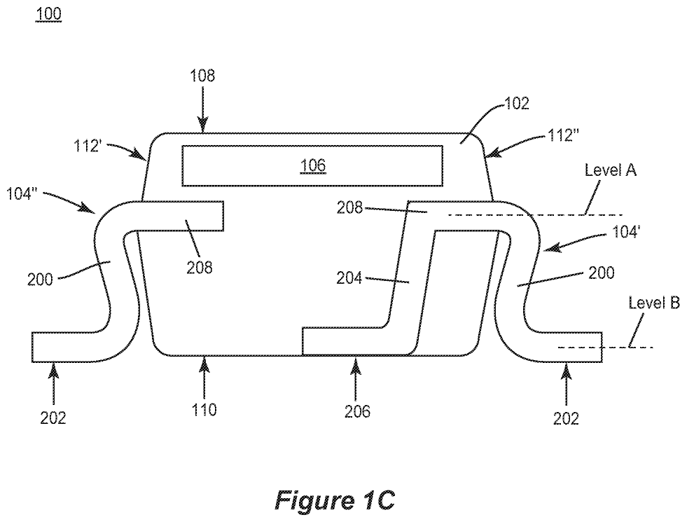

FIGS. 1A through 1C illustrate an embodiment of a molded semiconductor package 100 of the leaded type, FIG. 1A illustrates a side perspective view of the molded semiconductor package 100, FIG. 1B illustrates a bottom perspective view of the molded semiconductor package 100, and FIG. 1C illustrates a cross-sectional view of the molded semiconductor package 100 through the line labelled A-A′ in FIG. 1B.

The molded semiconductor package 100 includes a mold compound 102, leads 104 and at least one semiconductor die (chip) 106 embedded in the mold compound 102. The package 100 has a top side 108 and a bottom side 110 opposite the top side 108. The mold compound 102 has side faces 112 which extend between the top and bottom sides 108, 110 of the package 100. Any typical molding process such as injection molding, compression molding, film-assisted molding (FAM), reaction injection molding (RIM), resin transfer molding (RTM), map molding, blow molding, etc. may be used to embed the semiconductor die 106 in the mold compound 102. Common mold compounds and resins include, but are not limited to, thermoset resins, gel elastomers, encapsulants, potting compounds, composites, optical grade materials, etc.

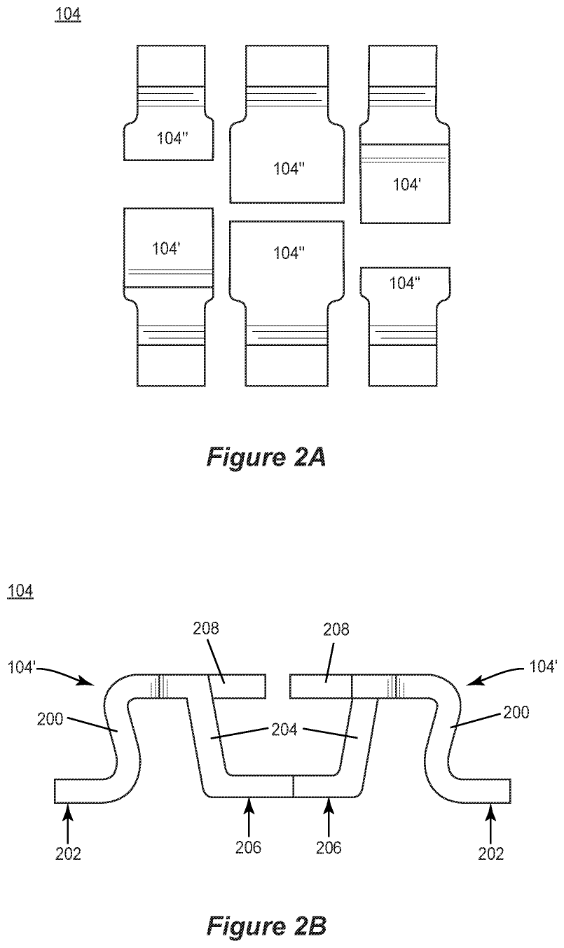

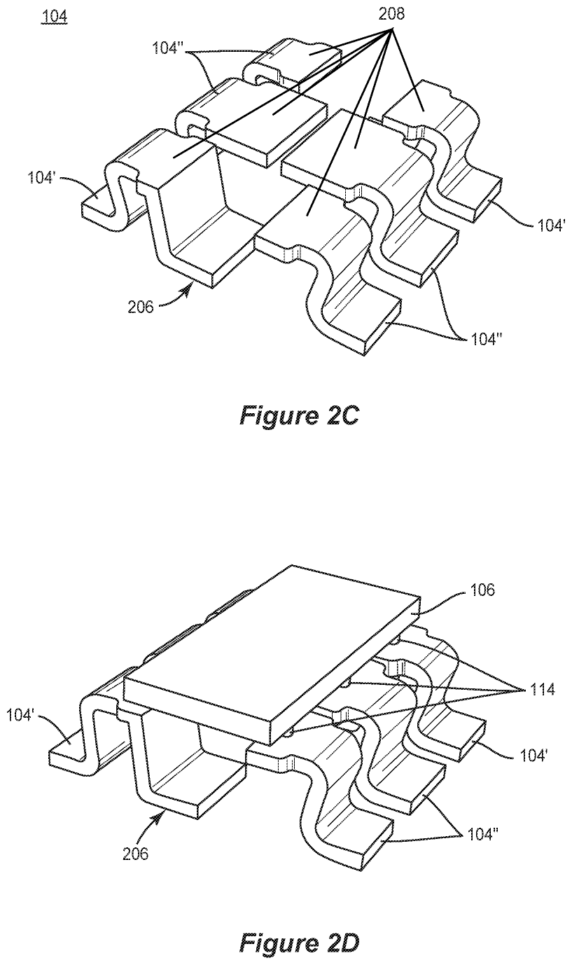

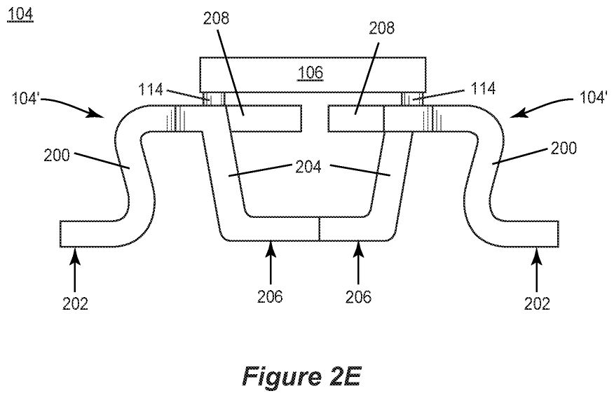

FIGS. 2A through 2E illustrate different views of the package 100 prior to the molding process. FIG. 2A illustrates a top plan view of the package leads 104 prior to die attach. FIG. 2B illustrates a side view of the package leads 104 prior to die attach. FIG. 2C illustrates a side perspective view of the package leads 104 prior to die attach, FIG. 2D illustrates the same side perspective view as FIG. 2C, but after die attach and before molding. FIG. 2E illustrates the same side view as FIG. 2B, but after die attach and before molding.

The leads 104 of the molded semiconductor package 100 transition from a first level (Level A′) within the mold compound 102 to a second level (level B′) outside the mold compound 102, the second level being different than the first level. The semiconductor die 106 embedded in the mold compound 102 is attached to the electrically conductive leads 104 in a flip-chip configuration. That is, the semiconductor die 106 is attached face-down to the leads 104 with connections 114 between the die and leads formed by solder bumps, Cu pillars, Cu-wire stud bumps, etc, which have lower resistance compared to traditional wire bonds. More than one semiconductor die 106 may be attached to the same set of package leads 104 and/or the molded semiconductor package 100 may include more than one set of package leads 104 with one or more semiconductor dies 106 attached to each set of package leads 104.

In each came, at least one lead 104′ of the plurality of package leads 104 has a first section 200 protruding from a side face 112 of the mold compound 102 and having a first end 202 which is positioned outside a footprint of the mold compound 102 and terminates at the second level (level B′), and a second section 204 embedded in the mold compound 102 and having a second end 206 which is positioned under the semiconductor die 106 and exposed at the bottom side 110 of the semiconductor package 100. The other leads 104″ have the first section 200, but not the second section 204.

The semiconductor die 106 embedded in the mold compound 102 is attached to a horizontal third section 208 of the leads 104. The third section 208 adjoins the first section 200 of each lead 104. In the case of the leads 104′ with the first and second sections 200, 204, the third section 208 is interposed between the first section 200 and the second section 204. Each lead 104′ with the second end 206 positioned under the semiconductor die 106 and exposed at the bottom side 110 of the semiconductor package 100 provides a thermal path which has a reduced thermal resistance.

The leads 104 may be formed from a single or double gauge lead frame, e.g., by stamping and/or etching. In the case of a single gauge lead frame, the leads 104 and heatsink (not shown) are the same thickness. In the case of a double gauge lead frame, the heatsink may be thicker or thinner than the leads 104 which requires the stamped leadframe to have two thicknesses. A thinner heatsink would allow for a thicker die. In either case, the individual leads 104 may be continuous. That is, the individual leads 104 may not have any joints or seams between the different lead sections 200, 204, 208.

Depending on the type of leaded package, the molded semiconductor package 100 may have leads 104 protruding from two, three or all four side faces 112 of the mold compound 102. For example, in the case of a dual row leaded flat package such as SOP like SSO8 or TSOP as shown in FIGS. 1A through 1C, some leads 104 protrude from a first side face 112′ of the mold compound 102 and other leads 104 protrude from a second side face 112″ of the mold compound 102 opposite the first side face 112′. In the case of a quad row leaded flat package such as QFP, the package would further include a third subset (not shown) of leads 104 protruding from a third side face of the mold compound 102 and a fourth subset (not shown) of leads 104 protruding from a fourth side face of the mold compound 102.

The leads 104 of the molded semiconductor package 100 are bent downward in a direction away from the top side 108 of the package 100 and toward the bottom side 110 of the package 100, e.g., in a gull-wing like configuration. In the embodiment shown in FIGS. 1A through 2E, two of the package leads 104′ each have the first section 200 and the second section 204 described above, so that two second lead ends 206 are exposed at the bottom side 110 of the semiconductor package 100 and may be electrically coupled to the same electric potential or to ground. For example, in the case of a power transistor die such as a power MOSFET (metal-oxide-semiconductor field effect transistor), IGBT (insulated gate bipolar transistor), HEMT (high-electron mobility transistor), etc., the second lead ends 206 exposed at the bottom side 110 of the semiconductor package 100 may be electrically coupled to source/emitter or drain/collector potential. With this configuration, ground potential may be better isolated from the other electrical connections to the die 106 with lower parasitic inductance. The first sections 200 of the leads 104′ with the second lead ends 206 exposed at the bottom side 110 of the semiconductor package 100 may protrude from opposite side faces 112 of the mold compound 102, e.g., as shown in FIGS. 1A through 2E.

In one embodiment, the mold compound 102 is a laser-activatable mold compound having a laser-activated region 116 at the bottom side 110 of the semiconductor package 100. The laser-activatable mold compound 102 includes at least one additive, e.g., in the form of an organic metal complex which is activatable by a physio-chemical reaction induced by a focused laser beam. The reaction cracks open the complex compounds in the mold compound 102 and breaks off metal atoms from the organic ligands. The freed metal atoms act as nuclei for metal or metal alloy (e.g. Cu, Ni, NiP, Au, Cu/Ni/Au stack, etc.) coating/plating in each region 116 of the mold compound 102 activated by a laser. The term “laser-activated region” as used herein mean a region of the laser-activatable mold compound 102 which has already been activated by a laser beam, as opposed to a laser-activatable region of the mold compound 102 which is capable of being activated by laser light but has yet to actually be activated. The laser-activated region 116 of the mold compound is plated with an electrically conductive material 118 which connects the second lead ends 206 exposed at the bottom side 110 of the semiconductor package 100. Such an approach allows for low resistance, direct electrical connection between the second lead ends 206 exposed at the bottom side 110 of the semiconductor package 100.

In one embodiment, the mold compound 102 has a recessed part 120 at the bottom side 110 of the semiconductor package 100 and the laser-activated region 116 is formed in the recessed part 120 of the mold compound 102, e.g., as shown in FIG. 1B. The recessed part 120 is surrounded by a thicker border/dam-like structure 122 of the mold compound 102. Each second lead end 206 exposed at the bottom side 110 of the semiconductor package 100 is exposed in the recessed part 120 of the mold compound 102 and surrounded by the mold compound border 122, according to this embodiment. The entire bottom surface of the mold compound 102 may instead be laser-activated and plated, e.g. with Cu, to electrically connect each second lead end 206 exposed at the bottom side 110 of the semiconductor package 100. According to this variant, a recess is not formed in the bottom surface of the mold compound 102. Instead, the bottom surface of the mold compound 102 remains generally flat.

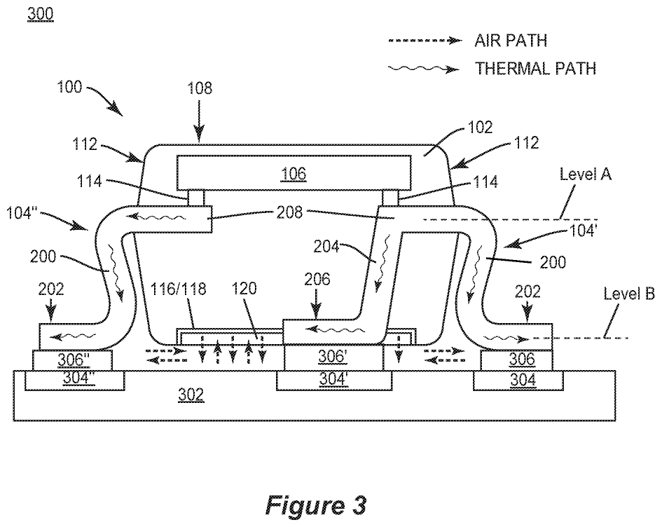

FIG. 3 illustrates an embodiment of an electronic assembly 300 that includes a board 302 such as a printed circuit board (PCB) and the molded semiconductor package 100 shown in FIGS. 1A through 2E attached to the board 302. As described above, at least one lead 104′ of the molded semiconductor package 100 has a first section 200 protruding from a side face 112 of the mold compound 102 and having a first end 202 which is positioned outside a footprint of the mold compound 102 and terminates at the second level (level B′), and a second section 204 embedded in the mold compound 102 and having a second end 206 which is positioned under the semiconductor die 106 and exposed at the bottom side 110 of the package 100. The first end 202 of the first section 200 of the lead 104′ is connected to a conductive region 304 of the board 302 such as a Cu trace, e.g., by solder 306. The second end 206 of the second section 204 of the lead 104′ also is connected to a conductive region 304′ of the board 302, e.g., by solder 306′. The other package leads 104″ are also connected to one or more conductive regions 304″ of the board 302, e.g., by solder 306″.

The main thermal path of the molded semiconductor package 100 is illustrated in FIG. 3. One part of the main thermal path is through the leads 104 and out the side faces 112 of the mold compound 102 to the board 302. Another part of the main thermal path is through each second lead end 206 exposed at the bottom side 110 of the semiconductor package 100 and to the board 302. The air path is also shown in FIG. 3. An empty pocket created by the recess 120 in the mold compound 102 at the bottom side 110 of the package 100 aids air circulation, providing additional heat release to the air. The empty pocket helps to spread the heat into a bigger area for more efficient heat dissipation. The plated laser-activated region 116 of the mold compound 102 at the bottom side 110 of the package 100 further improves the heat dissipation efficiency of the package 100.

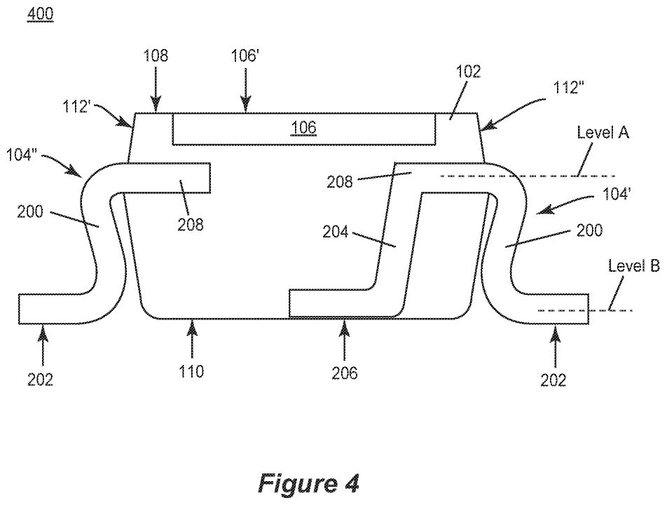

FIG. 4 illustrates another embodiment of a molded semiconductor package 400 of the leaded type. The embodiment shown in FIG. 4 is similar to the embodiment illustrated in FIGS. 1A through 3. Different, however, the side 106′ of the semiconductor die 106 facing away from the package leads 108 (and from the board 302 in FIG. 3) is exposed at the top side 108 of the semiconductor package 400. That is, at least a portion of the side 106′ of the semiconductor die 106 facing away from the package leads 104 is not covered by the mold compound 102. The top main surface of the mold compound 102 may be initially formed or later thinned so that the side 106′ of the semiconductor die 106 facing away from the package leads 104 is exposed at the top side 108 of the semiconductor package 400, the exposed top side 106′ being bare semiconductor material, e.g., bare silicon. According to the embodiment illustrated in FIG. 4, the thermal path of the molded semiconductor package 400 which includes the exposed surface of the semiconductor die 106 at the top side 108 of the package 400 has reduced the thermal resistance between the die 106 and the top side 108 the package 400 as compared to the package embodiment illustrated in FIGS. 1A through 3.

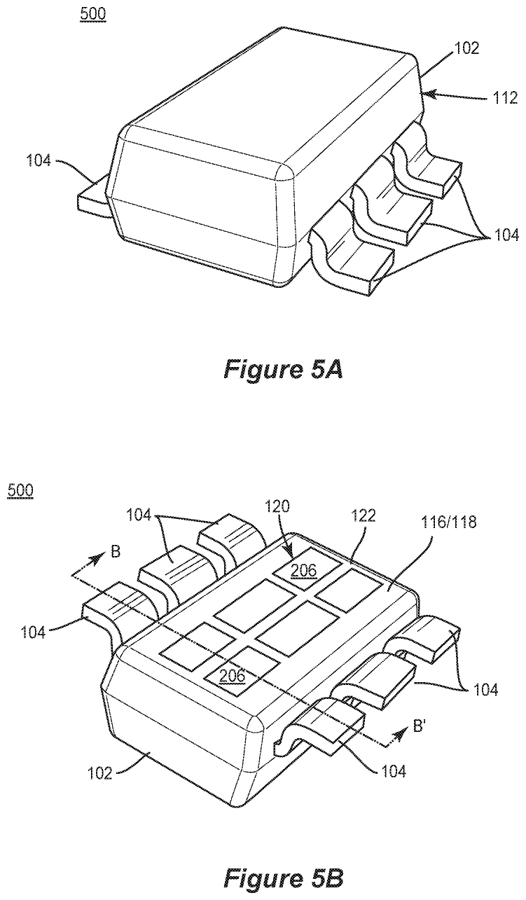

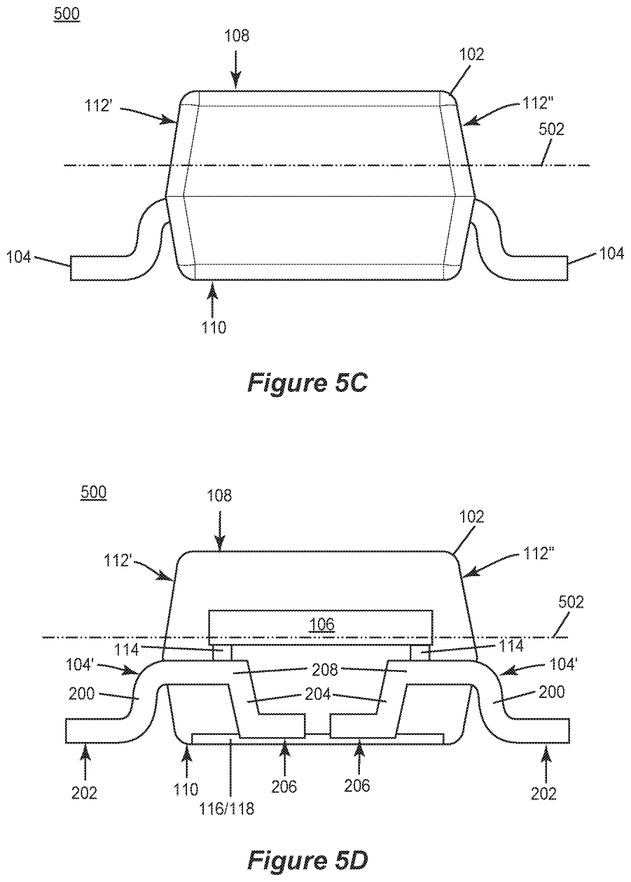

FIGS. 5A through 5D illustrate different views of another embodiment of a molded semiconductor package 500 of the leaded type. FIG. 5A illustrates a side perspective view of the molded semiconductor package 500, FIG. 5B illustrates a bottom perspective view of the molded semiconductor package 500, FIG. 5C illustrates a side view of the molded semiconductor package 500, and FIG. 5D illustrates a cross-sectional view of the molded semiconductor package 500 through the line labelled B-B′ in FIG. 5B. The embodiment shown in FIGS. 5A through 5D is similar to the embodiment illustrated in FIGS. 1A through 4. Different, however, the electrically conductive leads 104 protrude from the mold compound 102 below a horizontal centerline 502 of the mold compound 102. As such, the leads 104 have a lower downset as compared to the molded semiconductor package 100 illustrated in FIGS. 1A through 4.

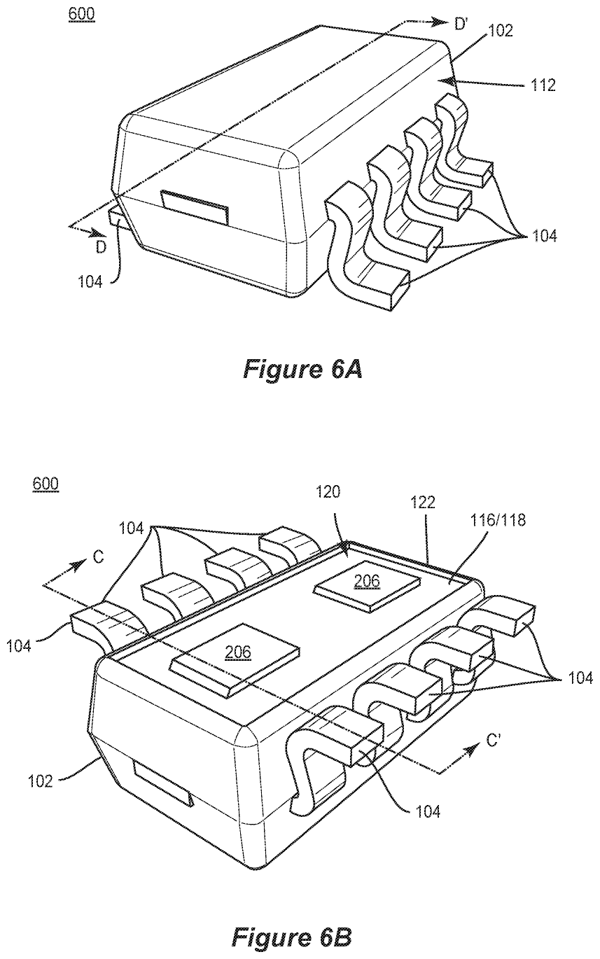

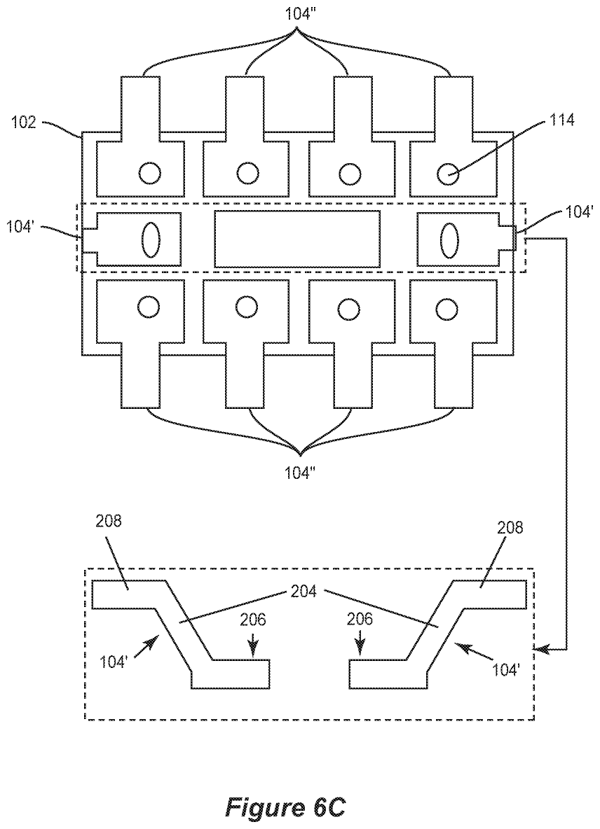

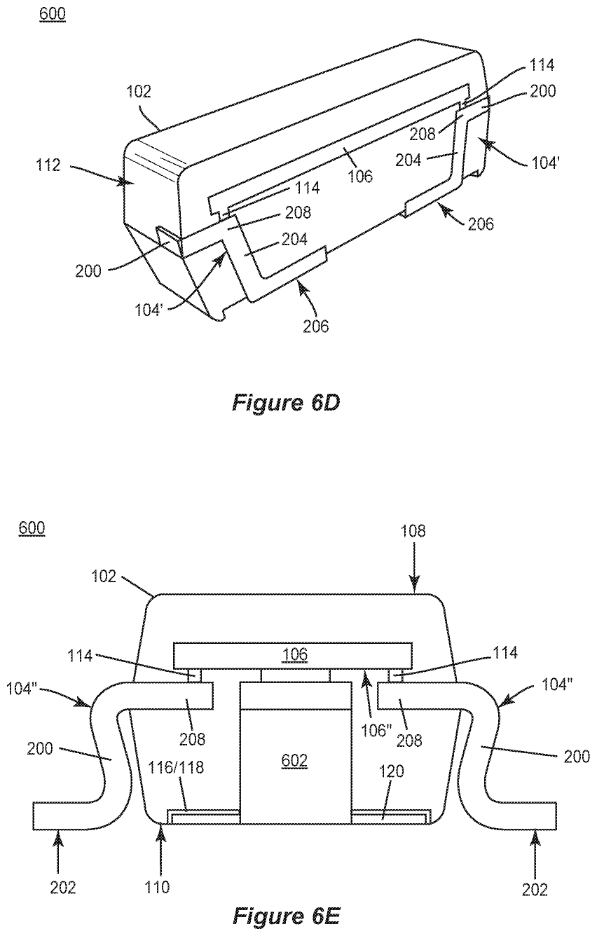

FIGS. 6A through 6E illustrate different views of another embodiment of a molded semiconductor package 600 of the leaded type. FIG. 6A illustrates a side perspective view of the molded semiconductor package. FIG. 6B illustrates a bottom perspective view of the molded semiconductor package. The upper part of FIG. 6C illustrates a horizontal sectional view through the package leads, whereas the lower part of FIG. 6C illustrates a partial cross-sectional view of the leads within the dashed box in the upper to show the leadframe downset employed to expose the second lead ends at the bottom side of the semiconductor package. FIG. 6D illustrates a perspective width-wise cross-sectional view of the molded semiconductor package through the line labelled C-C′ in FIG. 6B. FIG. 6E illustrates a lengthwise cross-sectional view of the molded semiconductor package through the line labelled D-D′ in FIG. 6A. The embodiment shown in FIGS. 6A through 6E is similar to the embodiment illustrated in FIGS. 1A through 4. Different, however, the molded semiconductor package has more leads 104. Also, at least some of the leads 104′ which have a second end 206 positioned under the semiconductor die 106 and exposed at the bottom side 110 of the semiconductor package 500 do not have the first section 200 which protrudes from a respective side face 112 of the mold compound 102 and has the first end 202 positioned outside the footprint of the mold compound 102 and which terminates at the second level (‘Level B’). Instead, these leads 104′ of the package 600 terminate at the respective side face 112 of the mold compound as shown in FIG. 6D.

The semiconductor package 600 also includes a metal block 602 contacting the side 106″ of the semiconductor die 106 to which the leads 104 are attached. The metal block 602 is exposed at the bottom side 110 of the semiconductor package 600 to provide increased heat dissipation. That is, at feast part of the metal block 602 is not covered by the mold compound 102 at the bottom side 110 of the package 600. In one embodiment, the metal block 602 is made of copper.

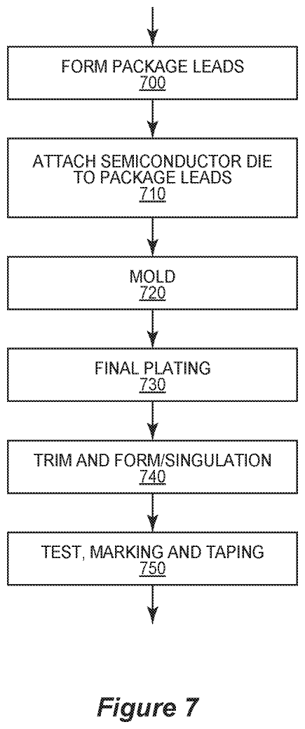

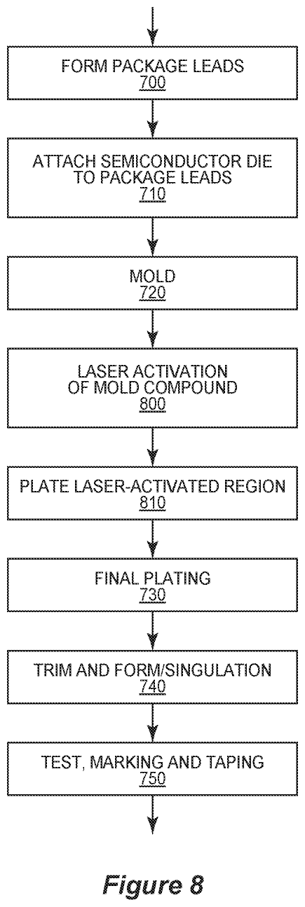

FIG. 7 illustrates an embodiment of a method of manufacturing the semiconductor packages 100, 400, 500, 600 described herein, without the laser-activated region. The method includes forming a plurality of electrically conductive leads from a leadframe, one or more leads of the plurality of electrically conductive leads including a first section and a second section (Block 700). For example, the package leads may be formed from a single or double gauge lead frame, e.g., by stamping and/or etching. The leadframe has a downset such that after package assembly, at least some of the leads transition from a first level (level A′) within the mold compound to a second level (level B′) outside the mold compound, the second level being different than the first level.

The method further includes attaching a semiconductor die to the leads in a flip-chip configuration (Block 710). The semiconductor die may be attached face-down to the leads with connections between the die and leads formed by solder bumps, Cu pillars, Cu-wire stud bumps, etc. The semiconductor die may be attached to a horizontal third section of each package lead having the first section and the second section, the third section being interposed between the first section and the second section.

The method further includes embedding the semiconductor die and the leads in a mold compound so that: at least some of the leads transition from a first level (‘Level A’) within the mold compound to a second level (level B′) outside the mold compound, the second level being different than the first level; the first section of the one or more leads terminates at a side face of the mold compound, or protrudes from the side face with a first end positioned outside a footprint of the mold compound and which terminates at the second level; and the second section of the one or more leads is embedded in the mold compound and the second end is positioned under the semiconductor die and exposed at a bottom side of the semiconductor package (Block 720). Any typical molding process such as injection molding, compression molding, film-assisted molding (FAM), reaction injection molding (RIM), resin transfer molding (RTM), map molding, blow molding, etc. may be used to embed the semiconductor die and package leads in the mold compound.

The method may further include final plating of the exposed leads (Block 730), trim and singulation in the case of multiple packages being fabricated from a common leadframe strip (Block 740), and test, marking and taping (Block 750).

FIG. 8 illustrates another embodiment of a method of manufacturing the semiconductor packages 100, 400, 500, 600 described herein, with the laser-activated region. The embodiment illustrated in FIG. 8 is similar to the method illustrated in FIG. 7. Different, however, the mold compound is a laser-activatable mold compound and at least two leads of the package leads have the first section and the second section so that at least two second lead ends are positioned under the semiconductor die and exposed at the bottom side of the semiconductor package after molding. According to this embodiment, the method further includes, prior to final plating of the packages leads, laser activating a region of the mold compound at the bottom side of the mold compound to form a laser-activated region (Block 800) and plating the laser-activated region with an electrically conductive material which connects the at least two second lead ends exposed at the bottom side of the semiconductor package (Block 810), both as previously described herein. The method may further include, prior to the laser activation, forming a recess in the mold compound at the bottom side of the semiconductor package, the recess being surrounded by a thicker border of the mold compound, e.g., as previously described herein in connection with FIG. 1B. The recess may be formed during the molding process or afterword. In either case, laser activation is performed on the recess in the mold compound to form the laser-activated region. The method may continue as described above in connection with FIG. 7, that is, with final plating of the exposed leads (Block 730), trim and singulation in the case of multiple packages being fabricated from a common leadframe strip (Block 740), and test, marking and taping (Block 750).

Terms such as “first”, “second”, and the like, are used to describe various elements, regions, sections, etc. and are also not intended to be limiting. Like terms refer to like elements throughout the description.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

It is to be understood that the features of the various embodiments described herein may be combined with each other, unless specifically noted otherwise.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

1. A semiconductor package, comprising:
a mold compound;
a plurality of electrically conductive leads at least some of which transition from a first level within the mold compound to a second level outside the mold compound, the second level being different than the first level; and
a semiconductor die embedded in the mold compound and attached to the plurality of electrically conductive leads in a flip-chip configuration,
wherein one or more leads of the plurality of electrically conductive leads comprises:
a first section terminating at a side face of the mold compound, or protruding from the side face with a first end positioned outside a footprint of the mold compound and which terminates at the second level; and
a second section embedded in the mold compound and having a second end which is positioned under the semiconductor die and exposed at a bottom side of the semiconductor package.

2. The semiconductor package of claim 1, wherein the semiconductor die is attached to a horizontal third section of the one or more leads having the first section and the second section, the third section being interposed between the first section and the second section.

3. The semiconductor package of claim 1, wherein at least two leads of the plurality of electrically conductive leads each comprise the first section and the second section so that at least two second lead ends are positioned under the semiconductor die and exposed at the bottom side of the semiconductor package, and wherein the at least two second lead ends positioned under the semiconductor die and exposed at the bottom side of the semiconductor package are electrically coupled to the same electric potential or to ground.

4. The semiconductor package of claim 3, wherein the mold compound is a laser-activatable mold compound having a laser-activated region at the bottom side of the semiconductor package, and wherein the laser-activated region is plated with an electrically conductive material which connects the at least two second lead ends positioned under the semiconductor die and exposed at the bottom side of the semiconductor package.

5. The semiconductor package of claim 4, wherein the laser-activated region is formed in a recessed part of the mold compound at the bottom side of the semiconductor package, and wherein the recessed part is surrounded by a thicker border of the mold compound.

6. The semiconductor package of claim 1, wherein the second end of the one or more leads of the plurality of electrically conductive leads is exposed in a recessed part of the bottom side of the semiconductor package, and wherein the recessed part is surrounded by a thicker border of the mold compound.

7. The semiconductor package of claim 1, wherein at least two leads of the plurality of electrically conductive leads each comprise the first section and the second section so that at least two second lead ends are positioned under the semiconductor die and exposed at the bottom side of the semiconductor package, and wherein the first section of a first one of the at least two leads and the first section of a second one of the at least two leads protrude from opposite side faces of the mold compound.

8. The semiconductor package of claim 1, wherein the plurality of electrically conductive leads protrude from the mold compound below a horizontal centerline of the mold compound.

9. The semiconductor package of claim 1, wherein a side of the semiconductor die facing away from the plurality of electrically conductive leads is exposed at a top side of the semiconductor package.

10. The semiconductor package of claim 1, further comprising a metal block contacting the side of the semiconductor die to which the plurality of electrically conductive leads is attached, wherein the metal block is exposed at the bottom side of the semiconductor package.

11. A method of manufacturing a semiconductor package, the method comprising:
forming a plurality of electrically conductive leads from a leadframe, one or more leads of the plurality of electrically conductive leads comprising a first section and a second section;
attaching a semiconductor die to the plurality of electrically conductive leads in a flip-chip configuration; and
embedding the semiconductor die and the plurality of electrically conductive leads in a mold compound so that:
at least some of the electrically conductive leads transition from a first level within the mold compound to a second level outside the mold compound, the second level being different than the first level;
the first section of the one or more leads terminates at a side face of the mold compound, or protrudes from the side face with a first end positioned outside a footprint of the mold compound and which terminates at the second level; and
the second section of the one or more leads is embedded in the mold compound and has a second end positioned under the semiconductor die and exposed at a bottom side of the semiconductor package.

12. The method of claim 11, wherein the mold compound is a laser-activatable mold compound and at least two leads of the plurality of leads have the first section and the second section so that at least two second lead ends are positioned under the semiconductor die and exposed at the bottom side of the semiconductor package, the method further comprising:
laser activating a region of the mold compound at the bottom side of the mold compound to form a laser-activated region; and
plating the laser-activated region with an electrically conductive material which connects the at least two second lead ends positioned under the semiconductor die and exposed at the bottom side of the semiconductor package.

13. The method of claim 12, further comprising:
forming a recess in the mold compound at the bottom side of the semiconductor package, the recess being surrounded by a thicker border of the mold compound,
wherein the laser activating is performed on the recess in the mold compound to form the laser-activated region.

14. An electronic assembly, comprising:
a board; and
a semiconductor package attached to the board and comprising:
a mold compound;
a plurality of electrically conductive leads at least some of which transition from a first level within the mold compound to a second level outside the mold compound and connected to the board, the second level being different than the first level; and
a semiconductor die embedded in the mold compound and attached to the plurality of electrically conductive leads in a flip-chip configuration,
wherein one or more leads of the plurality of electrically conductive leads comprises:
a first section terminating at a side face of the mold compound, or protruding from the side face with a first end positioned outside a footprint of the mold compound and which terminates at the second level and is connected to the board; and
a second section embedded in the mold compound and having a second end which is positioned under the semiconductor die, exposed at a bottom side of the semiconductor package and connected to the board.

15. The electronic assembly of claim 14, wherein at least two leads of the plurality of electrically conductive leads each comprise the first section and the second section so that at least two second lead ends are positioned under the semiconductor die and exposed at the bottom side of the semiconductor package and connected to the board, and wherein the at least two second lead ends positioned under the semiconductor die and exposed at the bottom side of the semiconductor package are electrically coupled to the same electric potential or to ground.

16. The electronic assembly of claim 15, wherein the mold compound is a laser-activatable mold compound having a laser-activated region at the bottom side of the semiconductor package, and wherein the laser-activated region is plated with an electrically conductive material which connects the at least two second lead ends positioned under the semiconductor die and exposed at the bottom side of the semiconductor package.

17. The electronic assembly of claim 16, wherein the laser-activated region is formed in a recessed part of the mold compound at the bottom side of the semiconductor package, and wherein the recessed part is surrounded by a thicker border of the mold compound so that the distance between the recessed part of the mold compound and the board is greater than the distance between the thicker border of the mold compound and the board.

18. The electronic assembly of claim 14, wherein the second end of the one or more leads of the plurality of electrically conductive leads is exposed in a recessed part of the bottom side of the semiconductor package, and wherein the recessed part is surrounded by a thicker border of the mold compound so that the distance between the recessed part of the mold compound and the board is greater than the distance between the thicker border of the mold compound and the board.

19. The electronic assembly of claim 14, wherein the plurality of electrically conductive leads protrude from the mold compound below a horizontal centerline of the mold compound.

20. The electronic assembly of claim 14, further comprising a metal block contacting the side of the semiconductor die to which the plurality of electrically conductive leads is attached, wherein the metal block is exposed at the bottom side of the semiconductor package.
